(19) United States
(12) Patent Application Publication
(10) Pub. No.: US 2010/0151603 A1
(43) Pub. Date: Jun. 17, 2010

(54) METHOD OF MANUFACTURING A RESONANT CAVITY OPTICAL RADIATION EMITTING DEVICE

(75) Inventors: Maria Eloisa CASTAGNA, Leonforte (ENNA) (IT); Anna Muscara, Patti (MESSINA) (IT)

Correspondence Address: HOGAN & HARTSON LLP, ONE TABOR CENTER, SUITE 1500, 1200 SEVENTEENTH ST, DENVER, CO, 80202, US

(73) Assignee: STMicroelectronics s.r.I., Agrate Brianza (MI) (IT)

(21) Appl. No.: 12/605,224

(22) Filed: Oct. 23, 2009

(30) Foreign Application Priority Data
Dec. 17, 2008 (IT) T02008A00941

(51) Int. Cl. H01L 33/00

(52) U.S. Cl. 438/29; 257/E33.067

(57) ABSTRACT

A method of manufacturing a device for emission of optical radiation integrated on a substrate of a semiconductor material includes the steps of forming a first mirror, a second mirror of a dielectric type, and an active layer comprising a main zone designed to be excited to generate the radiation. First and second electrically conductive layers are formed and arranged to produce a generation electric signal of an electric field to which an excitation current of the main zone is associated. A dielectric region is formed between the first and the second layers by partially oxidizing the first electrically conductive layer to and thereby obtaining a thermal oxide layer, to space out corresponding peripheral portions of the first and second layers so that the electric field present in the main zone is greater than that present between the peripheral portions thus favouring a corresponding generation of the excitation current in the main zone.

### RELATED APPLICATION

The present application claims priority of Italian Patent Application No. TO2008A00941 filed Dec. 17, 2008, which is incorporated herein in its entirety by this reference.

### FIELD OF THE INVENTION

The present invention relates to a method of manufacturing a resonant cavity optical radiation emitting device.

### BACKGROUND OF THE INVENTION

In recent years, remarkable research activity has been aimed at developing resonant cavity light emitting devices employed as light sources in the optical trans-mission field within a communication network. One such device is a Resonant Cavity Light Emitting Diode (RCLED). European Patent Publication No. EP 1 734 591 discloses a RCLED consisting of two dielectric mirrors and a resonant cavity consisting of the electroluminescent active layer. The resonant cavity region is defined by an edge structure laterally defining the optically and electrically active region thereof. This edge structure consists of a passivation oxide obtained by vapour phase deposition (VAPOX) on which a typical photolithographic process is then carried out to obtain the region of the resonant cavity. Such edge structure has a substantially trapezoidal section, since it is obtained by means of a wet etching, and thus isotropic, that etches tilted walls.

Thus, the shape of the resonant cavity depends on the inclination of the edge structure walls. The lateral dimensions of such region are influenced by the fact that the wet etching, being an isotropic etching, can have resolution losses which depend on the thickness of the film to be etched. Particularly, such lateral dimensions are greater than a micron.

Furthermore, the use of an oxide deposited by vapour phase requires high-temperature densification processes to promote the expulsion of the hydrogen that is present in the VAPOX film; such thermal treatments necessarily also involve the films of the device lower mirror, and can lead to thickness reductions, with resulting variation of the optical characteristics of the lower mirror compared to the upper one.

It is further noted that, due to the resonant cavity dimensions and shape, the threshold voltage and the operating voltage of such device are rather high, typically ranging between 25-30 V (threshold voltage) and 150-200 V (operating voltage).

Alternatively to RCLED devices, VCSEL (Vertical Cavity Surface Emitting Laser) devices can be employed.

### SUMMARY OF THE INVENTION

An object of the present invention is a method of manufacturing a resonant cavity optical radiation emitting device with electric pumping of the active layer having a structure being alternative to known structures, in which the threshold voltage and the operating voltage are lower than the values of the known devices.

A method of the present invention of manufacturing a device for emission of optical radiation integrated on a substrate of a semiconductor material, includes the steps of forming on the substrate a first mirror and a second mirror, wherein the second mirror is of a dielectric type; forming an active layer comprising a main zone to be excited to generate the radiation; forming a first and a second electrically conductive layers associated, respectively, with said first and second mirrors, and arranged to produce a generation electric signal of an electric field to which an excitation current of the active layer is associated, said main zone facing said first and second electrically conductive layers; and forming a dielectric region between said first and second electrically conductive layers by partially oxidizing the first electrically conductive layer to obtain a thermal oxide layer and space corresponding peripheral portions of said first and second electrically conductive layers, so that the electric field present in the main zone is greater than the one present between said peripheral portions thus favouring a corresponding generation of the excitation current in the main zone.

### BRIEF DESCRIPTION OF THE DRAWINGS

Further characteristics and advantages of the invention will be clear from the following detailed description, given purely by way of non-limiting example, with reference to the annexed drawings, in which:

FIGS. 1 to 7 are longitudinal cross-sectional views of several intermediate steps of a process of manufacturing a device according to the present invention;

FIG. 8 is a longitudinal cross-sectional view of a device manufactured according to the present invention.

### DETAILED DESCRIPTION OF PREFERRED EMBODIMENTS

Briefly, the invention relates to a method in which the dielectric region of the resonant cavity is manufactured, i.e., the edge structure, with a thermal oxidation step that allows obtaining a higher control of the lateral dimensions. In fact, such step does not require the use of high-temperature thermal densification processes, thus allowing a higher control of the resonant cavity thickness and avoiding the reduction of the lower mirror film thicknesses. Furthermore, the thermal oxide of such dielectric region has a lower structural defectiveness, and a higher insulating ability, it does not lead to adhesion problems between the films, thus avoiding possible peeling-offs of the layers, i.e., the release of the layers of such dielectric region.

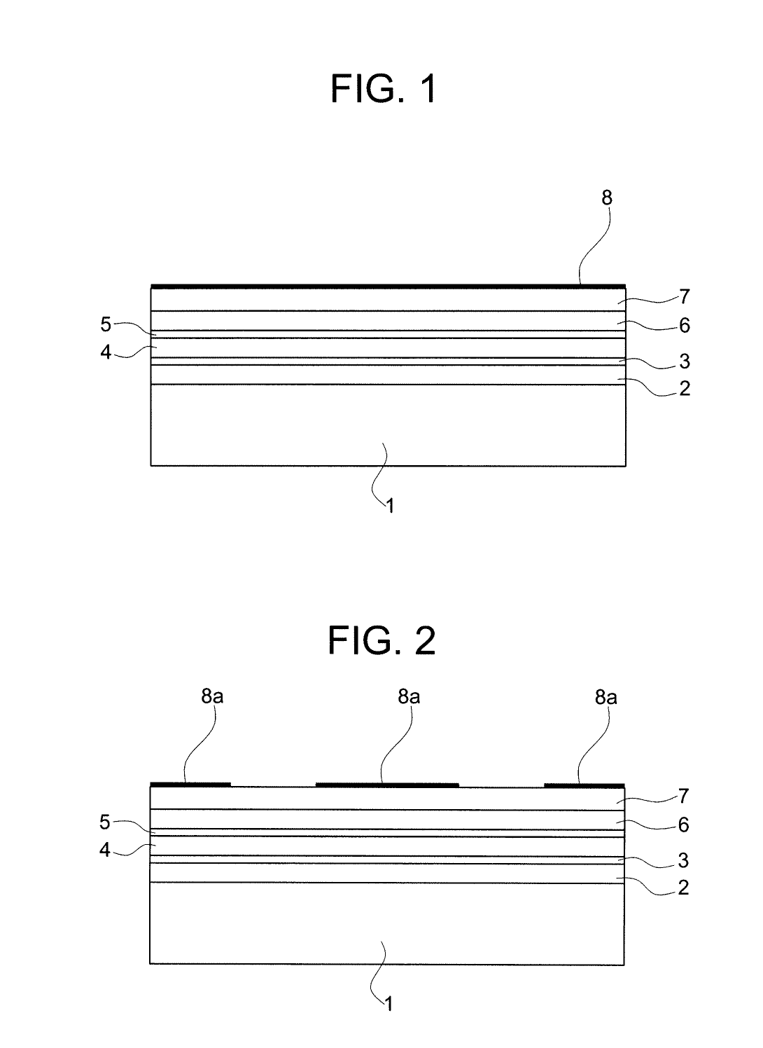

With reference to FIGS. 1 to 7, a process for manufacturing a RCLED device with an emission wavelength λ₀ is now described, in which the active layer that can be used is, preferably, of an SRO (Silicon Rich Oxide) type, i.e., silicon dioxide (SiO₂) enriched with silicon (Si), doped with erbium.

As shown in FIG. 1, on a support substrate 1, a first silicon dioxide layer 2 with thickness d₂ and refractive index n₂ is deposited. Alternatively, in the case where the support substrate is silicon, the silicon dioxide can be obtained by thermal growth. A first silicon nitride layer 3 that has refractive index n₃ and thickness d₃ is deposited on the first dioxide layer 2. Then, on the first silicon nitride layer 3, a second silicon dioxide layer 4 of thickness d₄ and refractive index n₄ is deposited. On the second silicon dioxide layer 4, a second silicon nitride layer 5 is deposited, having refractive index n₅ and thickness d₅. On the second silicon nitride layer 5, a third silicon dioxide layer 6 is deposited, having refractive index n₆ and thickness d₆.

Such sequence can be repeated several times thus increasing the reflectivity of the lower mirror consisting of a variable number of silicon nitride/silicon dioxide pairs with a suitable thickness and refractive index so that the product of the thickness by the refractive index of each layer is equal to λ₀/4, so as to satisfy the constructive interference condition for all the layers composing the mirror.

Alternatively to the silicon nitride and silicon dioxide pair, it is possible to use other pairs of materials having different refractive index and morphological and grid characteristics such as to be able to be coupled as to implement a dielectric mirror, for example, silicon and non-doped silicon dioxide.

On the third silicon dioxide layer 6, a first doped polysilicon layer 7 is deposited (preferably with doping of the P+ type). The doping can be obtained by doping the amorphous silicon layer during the deposition step or in a successive implanting step. This material has a refractive index n₇ and is deposited until reaching a thickness d₇.

On the first doped polysilicon layer 7, a silicon nitride layer 8 is deposited. Such nitride layer 8 is subsequently subjected to a photolithographic process (that comprises a first step of definition of a photo-mask and a second step of chemical dry photo-etching, or dry etching) to obtain a plurality of mask regions 8a (see FIG. 2) adapted to partially coat the doped polysilicon layer 7.

Alternatively to the silicon nitride, it is possible to use other materials that are suitable to act as a mask for the following steps.

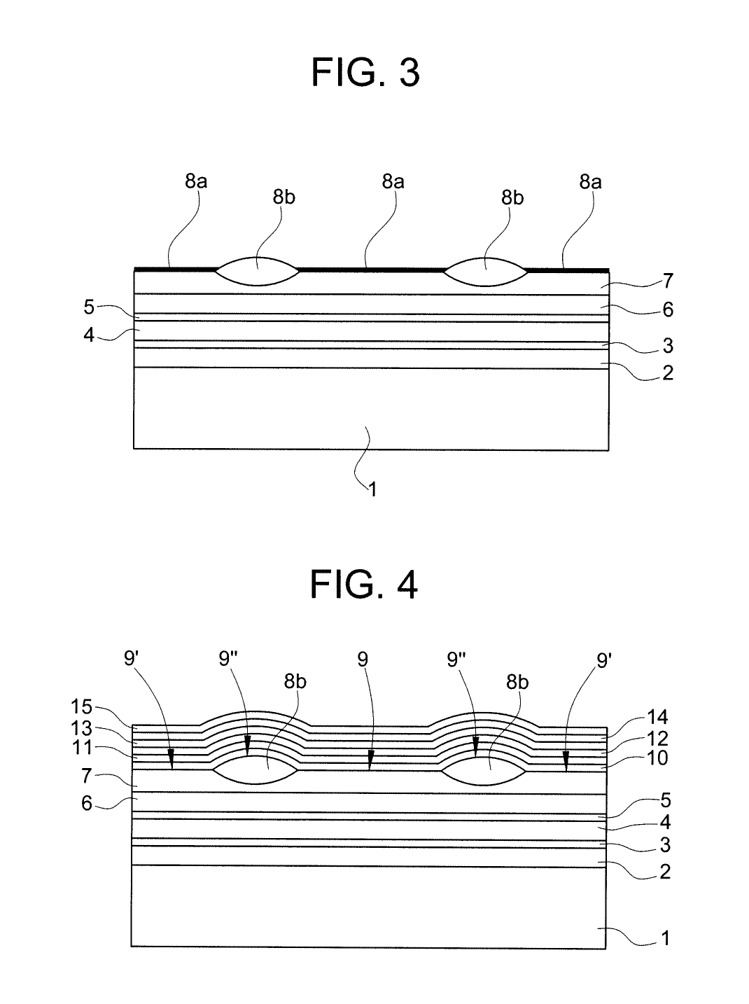

As shown in FIG. 3, an oxidation step of the doped polysilicon layer 7 is then carried out at the zones not coated by the mask regions 8a, that leads to the formation of a thermal oxide dielectric region 8b, with toroidal base (this characteristics is not visible in the Figure) having, for example, a thickness of 300 nm. The doped polysilicon layer 7 partially reduces the thickness thereof, following oxidation, in the zones at the dielectric region 8b; however, such polysilicon layer 7 is not completely “worn” following oxidation, thus maintaining an electric continuity of the same layer. The thermal oxide layer has a section with ellipse-shaped walls which serve to define the resonant cavity lateral dimensions.

Subsequently, (see FIG. 4) the silicon nitride layer 8 of the mask regions 8a is removed, and a deposition step of an active layer 10 is carried out, which follows morphologically the profile of the structure illustrated in FIG. 3. In more detail, the active layer 10 is in contact with the first electrically conductive layer 7 in a lateral region 9′ and in a first region 9, substantially defined within the dielectric region 8b, and in contact with said dielectric region 8b in a second region 9″. Such first region 9 has lateral dimensions that are below one micron.

The active layer 10 has refractive index n₁₀ and is deposited until reaching a thickness d₁₀. The thickness of the layer has to be such as not to interfere with the propagation of the electromagnetic wave within the cavity. The active layer that can be used, besides the above-mentioned SRO, can be SRO doped with rare earths such as, for example, terbium (Tb), ytterbium (Yb), or erbium (Eb). The possibility to use these rare earths as active layers is described in an article entitled High Efficiency Light Emitting Device In Silicon, by M. E. Castagna, et. al, Material Science and Engineering, pgs. 83-90.

Then a deposition is performed on top of the active layer 10, of a second electrically conductive layer 11. This is implemented, e.g., with N+ doped polysilicon. This material has refractive index n₁₁ and is deposited until reaching a thickness d₁₁. Such second N+ doped polysilicon layer 11 constitutes the upper boundary layer of the optical cavity which is thus created.

Therefore, the optical cavity results to be formed by the doped polysilicon layers 7 and 11 (which constitute the spacers) and by the active layer 10, while in EP 1 734 591, the optical cavity did not comprise the polysilicon layers 7 and 11.

The sum of the products of the thicknesses of the optical cavity layers by the respective refractive indexes has to be equal to an integer multiple of λ₀/2, so as to satisfy the destructive interference condition for all the layers constituting such cavity.

The first polysilicon layer 7 can be also doped only with N or P type.

With reference to FIG. 4, on the second doped polysilicon layer 11, a fourth silicon dioxide layer 12 is deposited, having refractive index n₁₂ and thickness d₁₂. On this fourth silicon dioxide layer 12, a third non-doped silicon nitride layer 13 is deposited, which has refractive index n₁₃ and thickness d₁₃. On the third non-doped silicon nitride layer 13, a fifth silicon dioxide layer 14 is deposited, having refractive index n₁₄ and thickness d₁₄. On the fifth silicon dioxide layer 14, a fourth silicon nitride layer 15 is deposited, having refractive index n₁₅ and thickness d₁₅.

In this case also, the sequence of the depositions can be repeated, thus obtaining a mirror with a suitable reflectivity, relative to the applications of interest, having the same interference properties described above with reference to the lower mirror, but with a smaller overall reflectivity. However, it is important that the sequence of the depositions is completed by the deposition of a silicon nitride layer with suitable thickness and refractive index. On the latter, as it will be described herein below, the deposition of a passivation oxide layer is provided for.

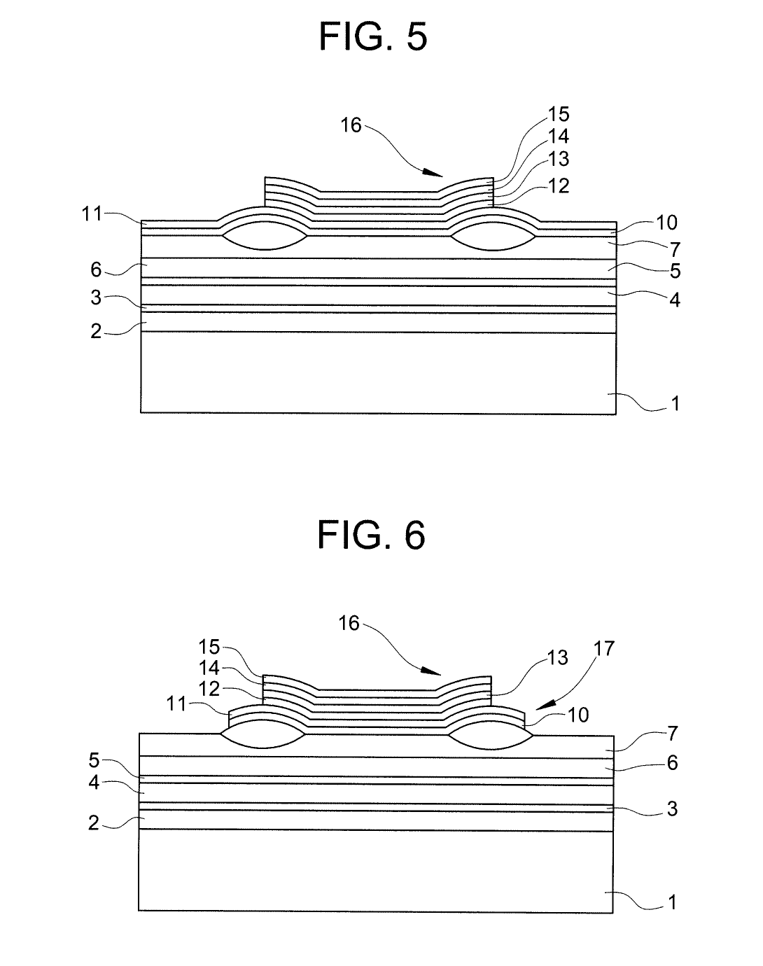

Next, a typical photolithographic process is carried out, that comprises a first definition step of the photo-mask and a second dry etching step to remove lateral portions of the layers 12, 13, 14 and 15 leaving a first multilayer structure 16 formed by the stack of said layers substantially aligned to the first region 9 and to part of the dielectric region 8b (FIG. 5) unaltered. The use of an anisotropic dry etching allows defining the multilayer structure with substantially vertical side walls.

Similarly, a photolithographic process follows, in which a photo-mask is defined, and a dry etching is performed in order to remove further lateral portions of the layers 10 and 11 to obtain a second multilayer structure 17 formed by the stack of said layers aligned to almost the whole part of the dielectric region 8b, and more extended than the first multilayer structure 16, as illustrated in FIG. 6.

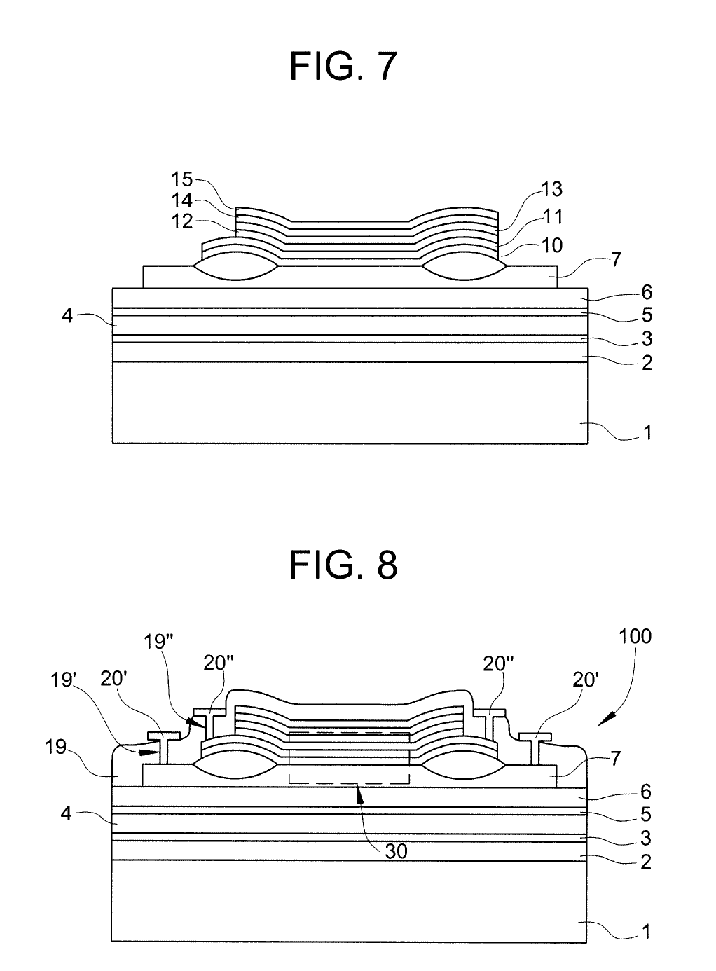

A successive photolithographic process comprises the definition of a photo-mask, whose profile exposes the first P+ doped polysilicon layer 7 to a dry etching step, following which peripheral portions of said first layer 7 are removed, thus obtaining the profile illustrated in FIG. 7, that leaves a peripheral portion of the layer 6 uncovered.

With reference to FIG. 8, on the structure of FIG. 7 a fifth oxide layer 19 is deposited, having refractive index n₁₉ and thickness d₁₉. Such layer acts as a passivation layer, and is part of the upper mirror. This is followed by an annealing step at a temperature ranging from 750° C. to 1100° C., or, alternatively, by a rapid thermal annealing (RTA) step to activate the doping of the polysilicon at a temperature of about 1000° C. for a duration of about 60 seconds. The selection of which one of the two thermal treatments is used depends on the active layer which is desired to activate. For example, in the case of erbium-doped SRO, an annealing at 800° C. is performed.

Subsequently, by a single lithographic process, respective grooves 19′ and 19″ are etched in the oxide layer 19. The first groove 19′ extends to the first polysilicon layer 7 and results to be, for example, external to the dielectric region 8b. The second groove 19″ extends deeply to the second doped polysilicon layer 11, surrounding the first multilayer structure 16 as shown in FIG. 8. Then, the electrically conductive material such as, for example, a metallization 20 is deposited. Next, a conventional photolithographic process is performed, for the definition of a photo-mask and an isotropic dry etching step to etch a first 20′ metallic region in the metallization 20, adapted to contact the first electrically conductive layer 7 through the first groove 19′. In the metallization 20, a second 20″ metallic region is further etched, adapted to contact the second electrically conductive layer 11, through the second groove 19″.

FIG. 8 illustrates the structure of the device 100 obtained by the above-described process.

The functions of the several layers reported above will be more clearly specified herein below. The substrate 1 is the support of the device 100, while the first silicon dioxide layer 2 can preferably have such characteristics as to insulate the same device from the substrate 1.

The layers 2 to 6 form a multilayer lower mirror DM comprising a plurality of pairs of silicon nitride-silicon dioxide layers.

The layers 12, 13, 14, 15, and 19 form a multilayer upper mirror UM comprising a plurality of pairs of silicon dioxide-silicon nitride layers. It shall be appreciated that the two mirrors are dielectric mirrors.

The active layer 10, the first P+ doped polysilicon layer 7, and the second conductive N+ doped polysilicon layer 11 define an optical cavity of the device 100, that is adapted to resonate at the emission wavelength λ₀.

The first 7 and the second 11 electrically conductive layers form the lower and upper boundary layers of the laser cavity, respectively. They allow applying a pumping electrical signal to the active layer 10, that is provided by the first 20′ and the second 20″ metallic regions of the metallization 20.

Furthermore, the first 7 and second 11 electrically conductive layers are obtained with a doping which increases the electrical conductivity thereof, and are adapted to establish, if they are provided with an electric signal, a mutual passage of current to which the generation of a respective electric field corresponds, the field lines of which have substantially a transversal direction to the plane of the two layers 7 and 11. The first 7 and the second 11 layers can be defined as electric armatures mutually opposite and divided by the active layer 10 in which the propagation of a substantially even electric field occurs.

Generally, the wavelength λ₀ value depends on the emission wavelength relative to the optical means, represented by the active layer 10 that can also have an emission in the visible light range in the case where, for example, it is non-doped SRO or silicon oxide doped with Terbium. The voltage required to start the functioning of the device is applied via the metallizations 20′ and 20″.

It shall be importantly noted that the dielectric region 8b increases the distance between the first 7 and the second 11 electrically conductive layers. On the contrary, in the first region 9, the first 7 and the second 11 electrically conductive layers are separated only by the active layer 10, thereby resulting more closer compared to what occurs at the dielectric region 8b.

Consequently, while keeping the voltage applied to the first 7 and second 11 electrically conductive layers constant, the electric field, in the active layer 10 portion corresponding to the first region 9, results to be greater than the one present at the dielectric region 8b. Therefore, in this portion of the active layer 10 directly facing the first 7 and the second 11 electrically conductive layers, the generation of an excitation electric current of the same active layer is favoured. The dielectric region 8b allows conveying the current towards the first region 9, thus favouring the emission that is amplified in the resonant cavity.

The dielectric region 8b, obtained as described before, is a thermal oxide defining the edge structure of the device. Compared to the edge structures manufactured with oxides obtained by vapour phase deposition, as reported in the devices present in the literature, such dielectric region 8b has a lower defectiveness, and therefore a higher electric stability, and allows the reduction of the thickness necessary to ensure the electric insulation outside the first region 9.

The process used to form dielectric region 8b allows for greater control of its thickness, since the film is not subjected to thermal processes to eliminate hydrogen, such as with vapour phase deposition processes. This also provides more control of the thickness of the lower mirror films, that are less susceptible to a thickness decrease.

The active layer 10 thickness has to be selected so as not to affect the cavity optical mode. The cavity portion corresponding to the first region 9 defines a radiation generation main zone, indicated in FIG. 8 with a dashed contour and a numeral reference 30.

The resonant cavity, therefore consisting of the first 7, the second 11 electrically conductive layers, and the active layer 10, has particular optical characteristics such as to ensure the necessary destructive interference and therefore the I-emission at λ₀.

In the proposed structure, advantageously, the first multilayer structure 16 has a width sufficient to ensure that the radiation main zone 30 is completely included between the upper mirror UM and the lower mirror DM. The cavity dimension is nλ/2 (with n>1), so as to be able to use thicker doped polysilicon layers 7 and 11, that allow an improvement in the electric operation of the device. As a result, the active layer 10 will be thinner, so that the above-mentioned relationship is satisfied. The active layer 10 low thickness favours a reduction of the threshold voltages, and improves the electric operation of the device. The cavity dimension has also to ensure a polysilicon 7 thickness sufficient to carry out a partial oxidation thereof in order to obtain the region 8b.

In Table 1, the reference thicknesses for use to manufacture the structure are reported, both in the case where the mirrors consist of alternate silicon dioxide and silicon nitride layers, and in the case where the mirrors consist of alternate silicon dioxide and non-doped silicon layers.

TABLE 1
Thicknesses of the Layers (nm) as a Function of λ₀ (nm)

| Layer | λ₀ = 1540 nm |
|---|---|
| Layers of silicon dioxide | 264 nm |
| Layers of silicon nitride | 190 nm |
| Layers of doped polysilicon | 210 nm |
| Active layer in SRO doped with erbium | 50 nm |
| Layers of silicon dioxide | 264 nm |
| Layers of non-doped silicon | 110 nm |
| Layers of doped polysilicon | 210 nm |
| Active layer in SRO doped with erbium | 50 nm |

The metallic regions 20′ and 20″ play the role of electric contacts, allowing providing the suitably generated pumping signal to the active layer 10. Particularly, the first metallic region 20′ contacts the first electrically conductive layer 7, while the second metallic region 20″ contacts the second electrically conductive layer 11. Both the first 20′ and the second 20″ regions have preferably an annular plant.

The pumping electrical signal is, preferably, a direct or alternated potential difference applied to the first 7 and second 11 electrically conductive layers, which generates a corresponding substantially even electric field in the active layer 10, that is, with field lines which are substantially transversal to the plane defined by the two layers 7 and 11. Typical values of this potential difference are 5-6 V, according to the application type, to the type of device used and the type of active layer 10.

The RCLED device 100, thanks to the electric pumping directly on the active layer 10, has a high emission efficiency. The presence of the resonant cavity allows obtaining optical radiation with selected wavelength λ₀ and high directionality.

The above-described invention can be implemented also for manufacturing a device of the VCSEL type, which is a laser source. Such VCSEL device can be structurally similar to the one described above and shown in FIG. 8, unless the active layer 10 is such as to provide an optical population inversion subsequent an electric pumping. In this case, it is necessary that the number of the pairs providing the dielectric mirrors requires to be suitably examined such as to obtain a suitable quality factor.

Some example of active layers that, at the current research state, are assumed to be suitable to give rise to population inversions are either SRO doped with erbium or a MQW (Multi Quantum Well) structure comprising nanometric silicon-silicon oxide layers.

An active layer including SRO doped with erbium is described in the above-cited article by M. E. Castagna et al.

As regards the erbium-doped SRO active layer 10, in such article is shown how it is possible to carry out an electric pumping of the erbium ions present in the SRO material, using such layer as a dielectric in the MOS (Metal Oxide Semiconductor) structure. However, the possibility to obtain a population inversion has not yet been proven.

The device 100 in accordance with the invention (of both RCLED and VCSEL type) is particularly suitable for application in the optical interconnections as an optical radiation source to be launched, for example, in optical waveguides either of the integrated or fibre technology type.

The device of the invention can be employed also for generating electromagnetic radiation in the visible range; by using, for example, a SRO or terbium-doped silicon oxide layer as active layer 10, an emission is obtained at a wavelength equal to 540 nm.

Clearly, the principle of the invention remaining the same, the embodiments and the implementation details will be widely varied compared to what has been described and illustrated above purely by way of non-limiting example, without thereby departing from the scope of the invention as defined in the annexed claims.

1. A method of manufacturing a device for emission of optical radiation integrated on a substrate of a semiconductor material, the method comprising:
forming on the substrate a first mirror and a second mirror, wherein the second mirror is of a dielectric type;
forming an active layer comprising a main zone to be excited to generate the radiation;
forming a first and a second electrically conductive layers associated, respectively, with said first and second mirrors, and arranged to produce a generation electric signal of an electric field to which an excitation current of the active layer is associated, said main zone facing said first and second electrically conductive layers; and
forming a dielectric region between said first and second electrically conductive layers by partially oxidizing the first electrically conductive layer to obtain a thermal oxide layer and space corresponding peripheral portions of said first and second electrically conductive layers, so that the electric field present in the main zone is greater than the one present between said peripheral portions thus favouring a corresponding generation of the excitation current in the main zone.

2. The method according to claim 1, wherein the first and second electrically conductive layers are placed in contact with the active layer in a first region thus defining the main zone of radiation generation.

3. The method according to claim 1, wherein the first mirror is formed on said substrate and comprises:
at least a first layer of electrically insulating material placed in contact with said substrate; and
at least a second layer of electrically insulating material placed in contact with said at least first electrically insulating layer.

4. The method according to claim 2, wherein the first mirror is formed on said substrate and comprises:
at least a first layer of electrically insulating material placed in contact with said substrate; and
at least a second layer of electrically insulating material placed in contact with said at least first electrically insulating layer.

5. The method according to claim 3, wherein said first and second electrically insulating layers in the first mirror have a respective thickness and a refractive index such that the first mirror creates constructive interferences for an emission wavelength of the device to reflect the optical radiation at said wavelength towards the active layer.

6. The method according to claim 4, wherein said first and second electrically insulating layers in the first mirror have a respective thickness and a refractive index such that the first mirror creates constructive interferences for an emission wavelength of the device to reflect the optical radiation at said wavelength towards the active layer.

7. The method according to claim 1, wherein the second mirror is formed on said second electrically conductive layer and comprises:
at least a third layer of electrically insulating material placed in contact with said second electrically conductive layer,
at least a fourth layer of electrically insulating material placed in contact with said at least third layer of electrically insulating material.

8. The method according to claim 2, wherein the second mirror is formed on said second electrically conductive layer and comprises:
at least a third layer of electrically insulating material placed in contact with said second electrically conductive layer,
at least a fourth layer of electrically insulating material placed in contact with said at least third layer of electrically insulating material.

9. The method according to claim 3, wherein the second mirror is formed on said second electrically conductive layer and comprises:
at least a third layer of electrically insulating material placed in contact with said second electrically conductive layer,
at least a fourth layer of electrically insulating material placed in contact with said at least third layer of electrically insulating material.

10. The method according to claim 4, wherein the second mirror is formed on said second electrically conductive layer and comprises:
at least a third layer of electrically insulating material placed in contact with said second electrically conductive layer,
at least a fourth layer of electrically insulating material placed in contact with said at least third layer of electrically insulating material.

11. The method according to claim 3, wherein said at least third and fourth electrically insulating layers included in the second mirror have a respective thickness and a respective refractive index such that the second mirror creates constructive interferences for an emission wavelength of the device to reflect the optical radiation at said wavelength towards the active layer.

12. The method according to claim 4, wherein said at least third and fourth electrically insulating layers included in the second mirror have a respective thickness and a respective refractive index such that the second mirror creates constructive interferences for an emission wavelength of the device to reflect the optical radiation at said wavelength towards the active layer.

13. The method according to claim 1, further comprising the step of creating a metallization to supply said current aimed at exciting the main zone.

14. The method according to claim 2, further comprising the step of creating a metallization to supply said current aimed at exciting the main zone.

15. The method according to claim 12, further comprising the step of creating a metallization to supply said current aimed at exciting the main zone.

16. The method according to claim 13, wherein the metallization comprises a first metallic region that contacts the first electrically conductive layer and a second metallic region that contacts the second electrically conductive layer to supply a pumping electrical signal to supply said current.

17. The method according to claim 16, further comprising:
furnishing to said first and second electrically conductive layer said pumping electrical signal as a direct or alternate potential difference.
